(19) United States
(12) Patent Application Publication
(10) Pub. No.: US 2012/0007211 A1
(43) Pub. Date: Jan. 12, 2012

(54) IN-STREET DIE-TO-DIE INTERCONNECTS

(76) Inventors: Aleksandar Aleksov, Chandler, AZ (US); Arnab Sarkar, Chandler, AZ (US); Henning Braunisch, Chandler, AZ (US); Jerry R. Bautista, Castro Valley, CA (US)

(21) Appl. No.: 12/830,547

(22) Filed: Jul. 6, 2010

(51) Int. Cl. H01L 27/10; H01L 21/50

(52) U.S. Cl. 257/508; 438/462; 257/E21.499; 257/E27.07

(57) ABSTRACT

The present disclosure relates to the field of microelectronic die packaging, particularly multi-chip packaging, wherein on-substrate modularity is enabled by using in-street die-to-die interconnects to facilitate signal routing between microelectronic dice. These in-street die-to-die interconnects may allow for manufacturing of several products on a single microelectronic substrate, which may lead to improved microelectronic die and/or microelectronic module harvesting and increased product yields.

### BACKGROUND

Microelectronic dice are generally formed on microelectronic substrates, such as silicon wafers. Once formed, the microelectronic dice are cut from the microelectronic substrates and processed to form microelectronic devices.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates a top plan view of a microelectronic substrate having in-street die-to-die interconnects between microelectronic dice formed in and on the microelectronic substrate;

FIG. 2 illustrates a top plan view of a microelectronic module;

FIG. 3 illustrates a top plan view of a microelectronic substrate having in-street die-to-die interconnects between microelectronic dice where microelectronic modules are mapped for dicing;

FIG. 4 illustrates a side cross-sectional view of an interconnect layer formed on a microelectronic substrate;

FIG. 5 illustrates a side cross-sectional view of an embodiment of an in-street die-to-die interconnect;

FIG. 6 illustrates a top plan view of the in-street die-to-die interconnect along line 6-6 of FIG. 5;

FIG. 7 illustrates a side cross-sectional view of another embodiment of an in-street die-to-die interconnect;

FIG. 8 illustrates a top plan view of the in-street die-to-die interconnect along line 8-8 of FIG. 7;

FIG. 9 illustrates a side cross-sectional view of yet another embodiment of an in-street die-to-die interconnect;

FIG. 10 illustrates a top plan view of the in-street die-to-die interconnect along line 10-10 of FIG. 9;

FIG. 11 illustrates a side cross-sectional view of still another embodiment of an in-street die-to-die interconnect;

FIG. 12 illustrates a top plan view of the in-street die-to-die interconnect along line 12-12 of FIG. 11; and

FIG. 13 is a flow diagram of a process of forming an in-street die-to-die interconnect.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description relate to the field of microelectronic die packaging, particularly multi-chip packaging, wherein modularity is enabled by using in-street die-to-die interconnects to facilitate signal routing between microelectronic dice. These in-street die-to-die interconnects may allow for manufacturing of several products on a single microelectronic substrate, which may lead to improved microelectronic die and/or microelectronic module harvesting and increased product yields.

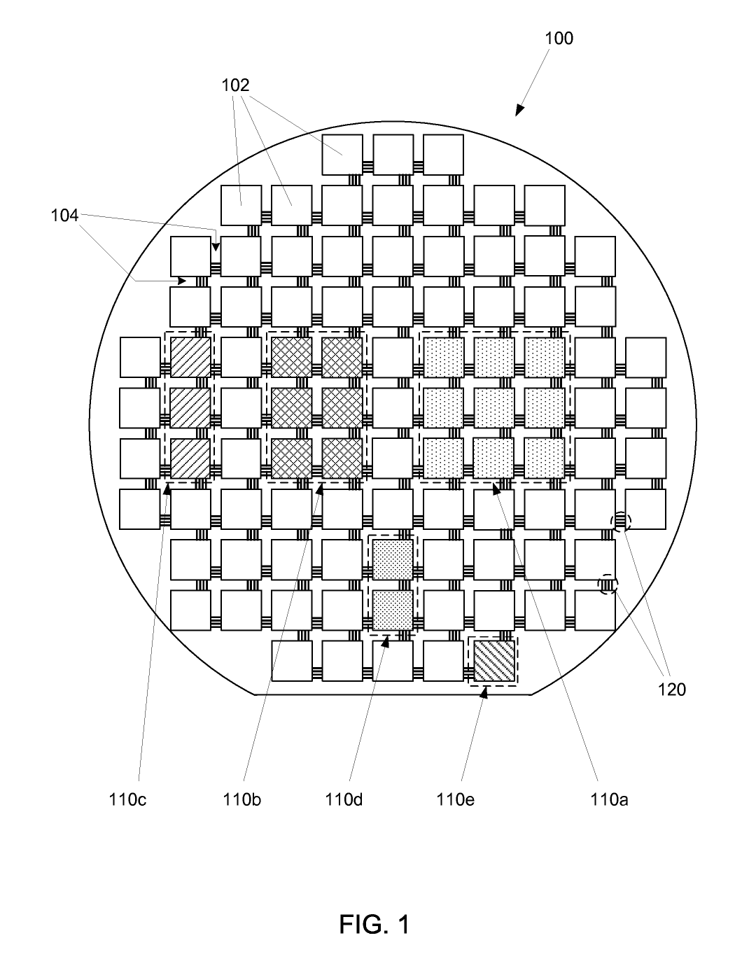

In the production of microelectronic devices, integrated circuitry may be formed in and on microelectronic device substrates. As shown in FIG. 1, a single microelectronic device substrate 100, such as a silicon or a silicon-germanium wafer, may contain a plurality of substantially identical integrated circuits forming a plurality of microelectronic dice 102, such as microprocessors, chipsets, graphics devices, wireless devices, memory devices, application specific integrated circuits, or the like, which are usually substantially rectangular and arranged in rows and columns. In general, two sets of mutually parallel dicing streets 104 may extend perpendicular to each other over substantially the entire surface of the microelectronic device substrate 100 between each discrete microelectronic die 102.

After the microelectronic dice 102 on the microelectronic device substrate 100 have been subjected to preliminary testing for functionality (wafer sort), the microelectronic device substrate may be diced (cut apart), so that each area of functioning integrated circuitry becomes an individual microelectronic die or so that selected sets of functioning integrated circuitry become a microelectronic module, such a first microelectronic module 110a, a second microelectronic module 110b, a third microelectronic module 110c, a fourth microelectronic module 110d, and a fifth microelectronic module 110e, which can be used to form a packaged microelectronic device.

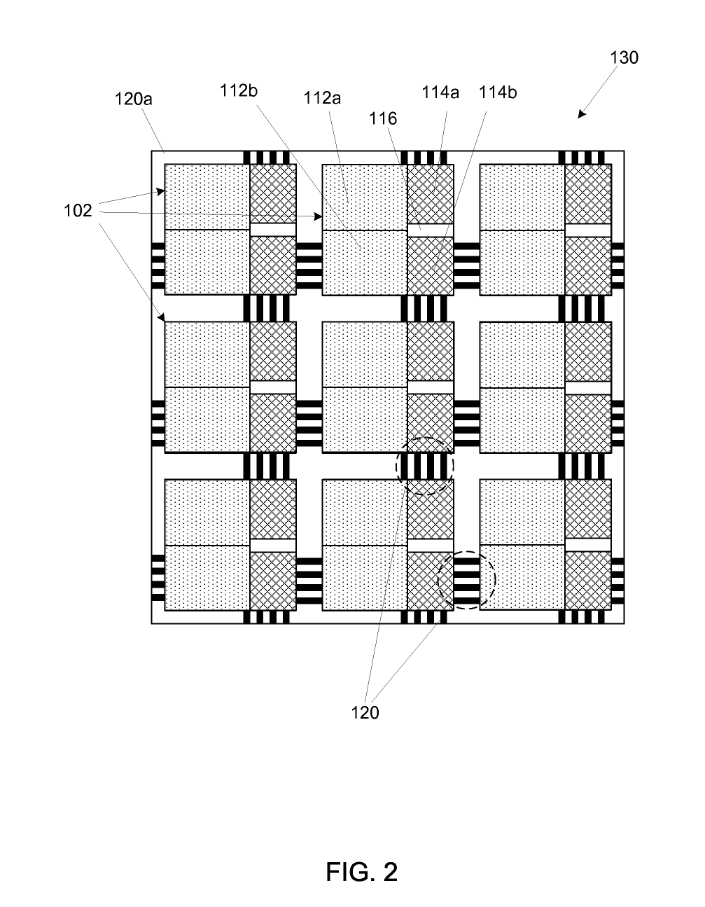

FIG. 2 shows one embodiment of the present disclosure where the first microelectronic module 110a, comprising a grouping 130 of nine (9) microelectronic dice 102, is cut from the microelectronic device substrate 100 of FIG. 1. Each of the nine microelectronic dice 102 may include a first processor core 112a and its respective first cache memory 114a, and a second processor core 112b and its respective second cache memory 114b. Each of the nine microelectronic dice 102 may also include a router 116 which may facilitate signal transmission between the microelectronic dice 102 within the first microelectronic module 110a, as well as facility communication to an external memory controller (not shown).

As each microelectronic die 102 has two processor cores, the first microelectronic module 110a would be an eighteen (18) core module. Likewise, referring to FIG. 1, the second microelectronic module 110b may be a twelve (12) core module, the third microelectronic module 110c may be a six (6) core module the fourth microelectronic module 110d may be a four (4) core module, and the fifth microelectronic module 110e may be a two (2) or dual core module.

As shown in FIGS. 1 and 2, each microelectronic die 102 includes at least one in-street die-to-die interconnect 120 extending through and/or over the dicing streets 104 to adjacent microelectronic dice 102. Thus, computational power can be sized by determining the number of cores in a module which is cut out of the microelectronic device substrate 100. Therefore, modularity is achieved by the in-street die-to-die interconnects 120 interconnecting the microelectronic dice 102, as will be discussed.

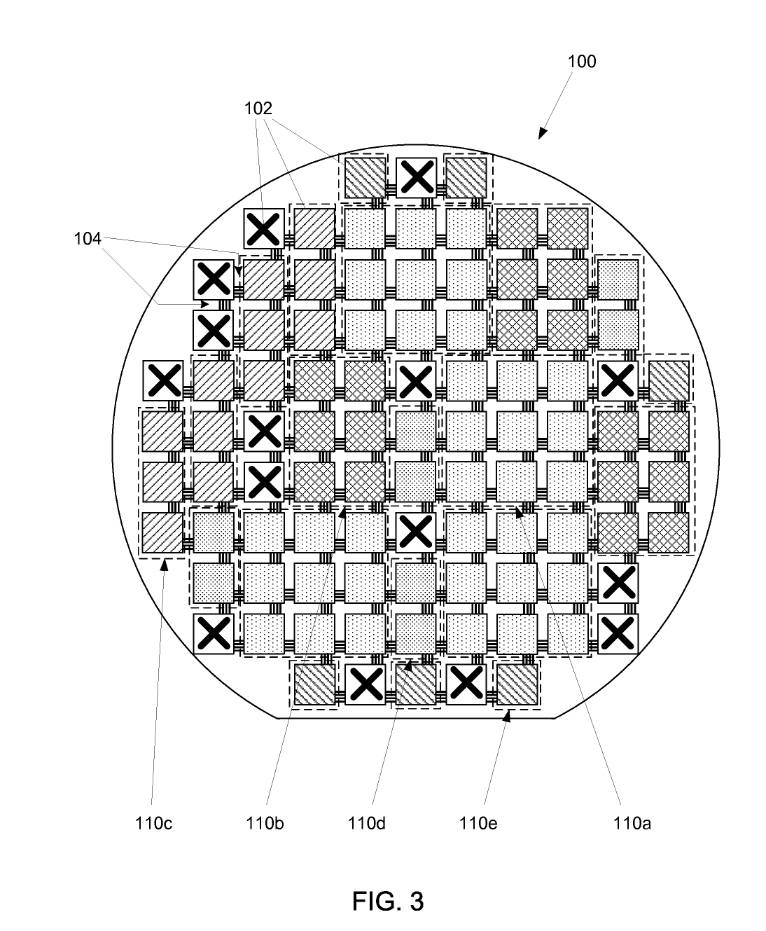

The embodiments of the present description may enable several modules to be cut from a single microelectronic device substrate 100. As shown in FIG. 3, losses due to non-functioning integrated circuits of the microelectronic dice 102, which are demarked with an X, may be minimized by optimal placement of the modules on the microelectronic device substrate 100. Thus, the harvesting of the microelectronic dice 102 may be improved and associated costs may be minimized.

Currently, if one or more microelectronic dice 102 within a microelectronic module are defective, the microelectronic module is still used in its own form factor and sold as a product with lower core count (for example, a 3-core product would be a 4-core product with one microelectronic die). However, these more complex products cannot be mated to a simpler package that may already be designed and used for native 3-core or 2-core products. It must be packaged with a more expensive package substrate to fit its larger form factor. Embodiments of the present description would permit cutting out modules only having functioning cores. Thus, the modules would use packaging components that are specific to their size, which would, of course, reduce packaging costs.

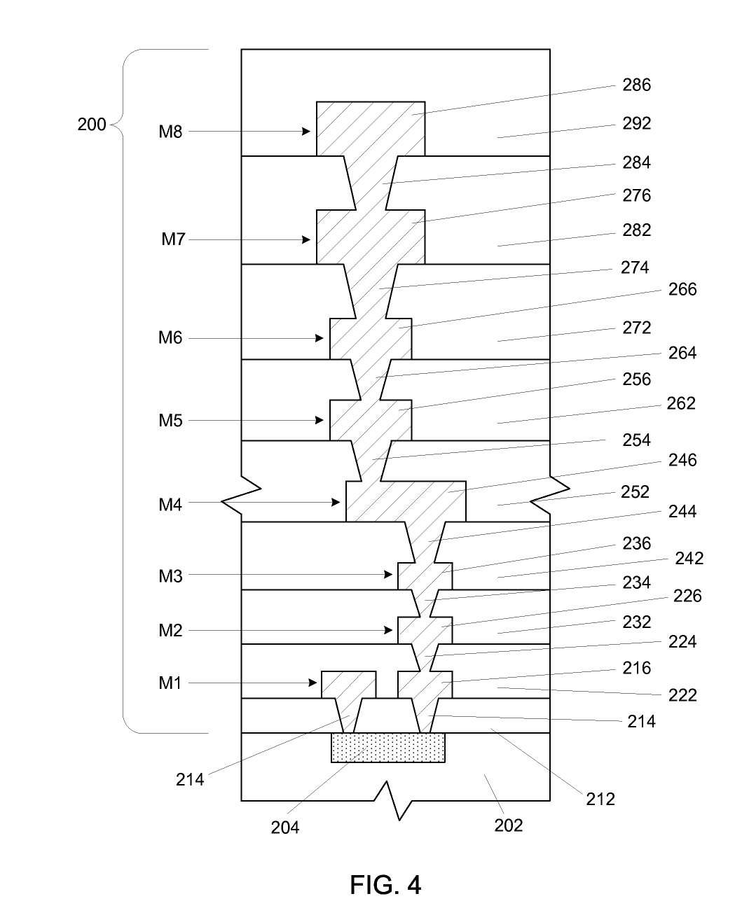

FIG. 4 illustrates an interconnect layer 200 showing a first dielectric layer 212 formed on a microelectronic substrate 202, which may have at least one integrated circuit 204 formed therein. A first metal layer M1, comprising at least one first conductive trace 216, may be formed on the first dielectric layer 212. The conductive trace(s) 216 may be in electrical communication with the integrated circuit 204 through a first conductive via 214. A second dielectric layer 222 may be formed on the first metal layer M1 and the first dielectric layer 212.

A second metal layer M2, comprising at least one second conductive trace 226, may be formed on the second dielectric layer 222. The conductive trace(s) 226 may be in electrical communication with at least one first conductive trace 216 through a second conductive via 224. This may be repeated to form a third metal layer through an eighth metal layer (elements M3, M4, M5, M6, M7, and M8, respectively), a third dielectric layer through a ninth dielectric layer (elements 232, 242, 252, 262, 272, 282, and 292, respectively), a third conductive via through an eight conductive via (elements 234, 244, 254, 264, 274, and 284, respectively), and a third conductive trace through an eight conductive trace (elements 236, 246, 256, 266, 276, and 286, respectively). The last metal layer may be defined as the uppermost metal layer, which in this illustration is M8.

The dielectric layers (e.g. elements 212, 222, 232, 242, 252, 262, 272, 282, and 292) of the interconnect layer 200 may be any appropriate dielectric material, including but not limited to a silicon dioxide, silicon nitride, and low-K dielectric materials (i.e. dielectric materials with a dielectric constant “K” lower than that of silicon oxide), including but not limited to carbon doped silicon dioxide and fluorine doped silicon dioxide. The dielectric layers may be formed by any known techniques, including but not limited to chemical vapor deposition and physical vapor deposition.

The conductive traces (e.g. elements 216, 226, 236, 246, 256, 266, 276, and 286) and the conductive vias (elements 214, 224, 234, 244, 254, 264, 274, and 284) may be any appropriate conductive material, including but not limited to copper, aluminum, gold, and alloys thereof. The conductive traces and conductive vias may be formed by any combination of techniques including, but not limited to lithographic techniques, plating techniques, deposition techniques, and the like.

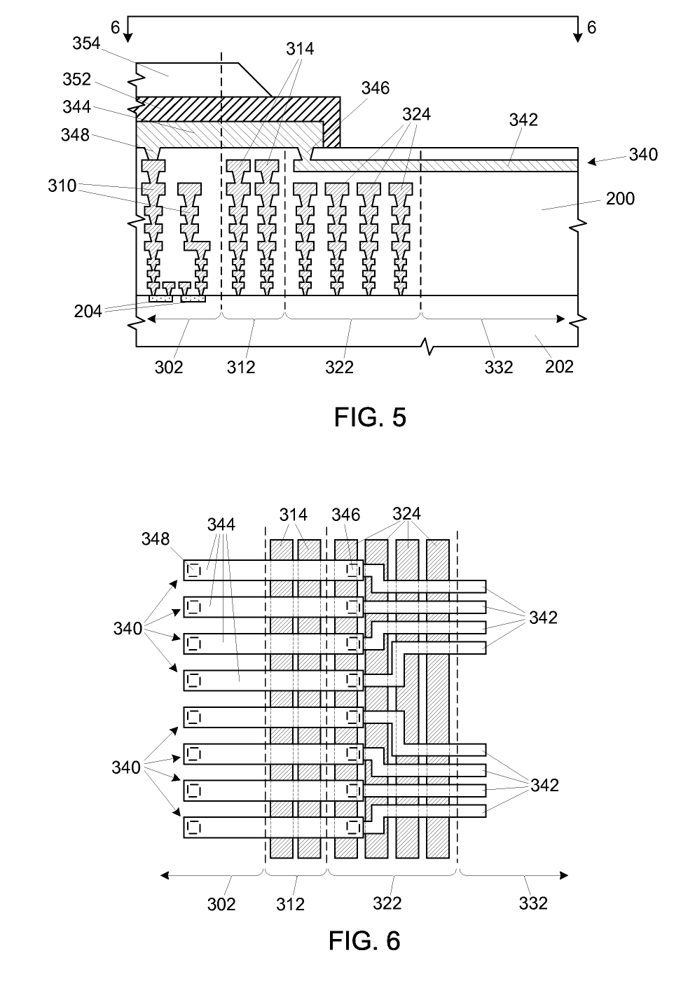

FIG. 5 illustrates an embodiment of an in-street die-to-die interconnect of the present description and FIG. 6 illustrates the embodiment illustrated in FIG. 5, along line 6-6, with all elements removed with the exception of the elements numbered in FIG. 6. The interconnect layer 200 may be formed on the microelectronic substrate 202 in the manner described with regard to FIG. 4. Within an active area 302 (i.e., where the integrated circuits 204 are formed in and on the microelectronic substrate 202), the metal layers (e.g., M1-M8 (see FIG. 4)) form communication routes 310 between various circuitry within the active area 302. Within a guard ring area 312 and within a moat area 322, the metal layers (e.g., M1-M8 (see FIG. 4)) form guard ring structures 314 and moat structures 324, respectively, which form walls that substantially surround the active area 302, as will be understood to those skilled in the art. The guard ring structures 314 and the moat structures 324 may assist in preventing external contamination encroaching into the integrated circuitry 204.

As shown in FIG. 5, the guard ring area 312 may be bridged with a bridge structure 344 formed on the interconnect layer 200. The bridge structure 344 may form an electrical route from an active area communication route 310 through a bridge structure-to-route via 348 to an in-street conductive trace 342 through a route-to-conductive trace via 346. The in-street conductive trace 342 may be formed in the uppermost metal layer, illustrated as M8 (see FIG. 4), over the moat area 322 and extend into a dicing street area 332 (and may extend to an adjacent microelectronic die (not shown) and may be in electrical contact therewith in the same manner). Thus, the in-street die-to-die interconnect 340 of present embodiment is a combination of the bridge structure 344 and the in-street conductive trace 342.

It is understood that the bridge structure 344 may be made by any known technique. In one embodiment, the bridge structure 344 may be formed with the same process as the fabrication of a first thick metal layer TM1 (illustrated in FIGS. 8, 10, and 12). The first thick metal layer TM1 is a metal layer formed during the fabrication of contact lands (not shown). These contact lands are generally in electrical communication with at least one of the active area communication routes 310 and act as platforms for the fabrication of conductive attachment structures (not shown), such as copper pillars that may be used to make electrical contact with an external component (not shown), as will be understood to those skilled in the art. An insulation layer 352, such as silicon nitride, may be formed over the bridge structure 344, and a protective resist layer 354, such as a photoresist material, may be formed over the insulation layer.

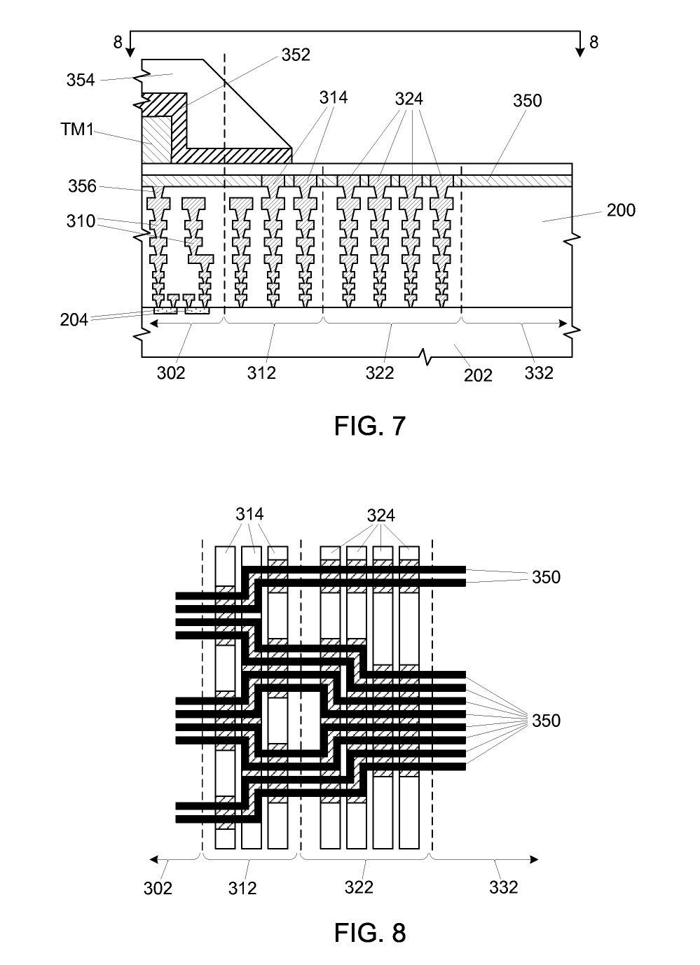

FIG. 7 illustrates another embodiment of an in-street die-to-die interconnect of the present description and FIG. 8 illustrates the embodiment illustrated in FIG. 7, along line 8-8, with all elements removed with the exception of the elements numbered in FIG. 8. The components of the microelectronic die shown in FIG. 7 are similar to those of FIG. 5. However, rather than a bridge structure 344, the in-street die-to-die interconnect 350 of the present embodiment may be formed entirely in the uppermost metal layer (illustrated as M8 (see FIG. 2)) and may be formed at the same time and in the same manner as the uppermost metal layer. As shown in FIG. 7, each of the in-street die-to-die interconnects 350 may contact at least one active area communication route 310 (such as through a conductive via 356), extend through the guard ring area 312, extend through the moat area 322, and into the dicing street area 332. It is understood that the in-street die-to-die interconnects 350 may extend to and be in communication with an adjacent microelectronic die (not shown) in the same manner.

As shown in FIG. 8, it will be necessary for the in-street die-to-die interconnects 350 break the continuity of the guard ring structures 314 on the uppermost metal layer (illustrated as M8 (see FIG. 2)). Furthermore, the guard ring area 312 may need to be widened, as the in-street die-to-die interconnects 350 may need to be designed with a serpentine route, as shown in FIG. 8, through the guard ring area 312 in order to inhibit cracking between the dielectric layers (see FIG. 2) in the interconnect layer 200, as will be understood to those skilled in the art.

Although the embodiment shown in FIGS. 7 and 8 illustrates the in-street die-to-die interconnects 350 formed in the uppermost metal layer (illustrated as M8 (see FIG. 2)), it is understood that the interconnects 350 may be formed anywhere in the interconnection layer 200, such as metal layers M1-M8 of FIG. 2, including ground traces and/or planes, as will be understood to those skilled in the art. Furthermore, the interconnects 350 may be formed on multiple metal layers, rather than on the illustrated single layer.

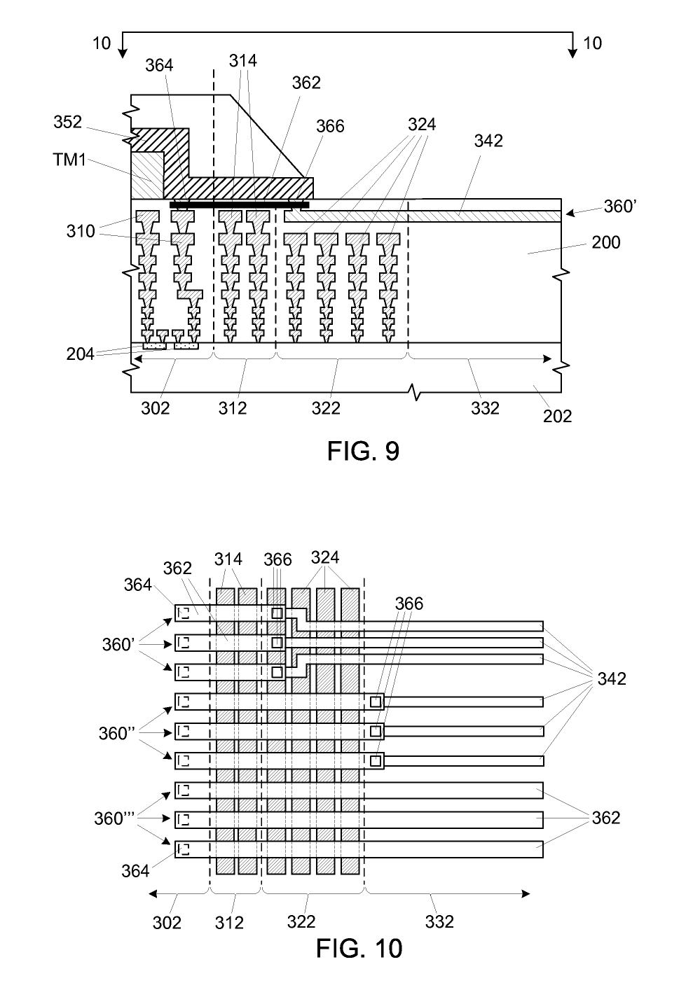

FIG. 9 illustrates yet another embodiment of an in-street die-to-die interconnect of the present description and FIG. 10 illustrates the embodiment illustrated in FIG. 9, along line 10-10, with all elements removed with the exception of the elements numbered in FIG. 10. The components of the microelectronic die shown in FIG. 9 are similar to those of FIG. 5. However, rather than a bridge structure 344 over the interconnect layer 200, in one embodiment, an embedded metal bridge 362 may be formed in an upper portion of the interconnect and may bridge over the guard ring area 312, connecting the active area communication route 310 (such as through a conductive via 364) to the conductive trace 342 (such as through a conductive via 366) extending over the moat area 322 and into the dicing street area 332 to form an in-street die-to-die interconnects 360′ of FIGS. 9 and 10. In another embodiment, the embedded metal bridge 362 may bridge over the guard ring area 312 and the moat area 322, connecting the active area communication route 310 (such as through the conductive via 364) to a conductive trace 342 (such as through the conductive via 366), which extends into the dicing street area 332 to form an in-street die-to-die interconnects 360″ of FIG. 10. In still another embodiment, the embedded metal bridge 362 may extend over the guard ring area 312, the moat area 322, and the dicing street area 332, itself forming an in-street die-to-die interconnects 360′″ of FIG. 10. It is understood that the in-street die-to-die interconnects 360′, 360″, and 360′″ may extend to and be in communication with an adjacent microelectronic die (not shown) in the same manner. The embedded metal bridge 362 may be formed by any techniques known in the art, including etching and plating.

As can be seen in FIGS. 9 and 10, the embedded metal bridge 362 does not compromise either the guard ring structures 314 or the moat structures 324 and may allow for high input/out density of about 500 in-street die-to-die interconnects per millimeter. In instances when the embedded metal bridge 362 is thin, in-street die-to-die interconnect 360′ or in-street die-to-die interconnect 360″ may be used to minimize signal loss and signal delay, as will be understood to those skilled in the art.

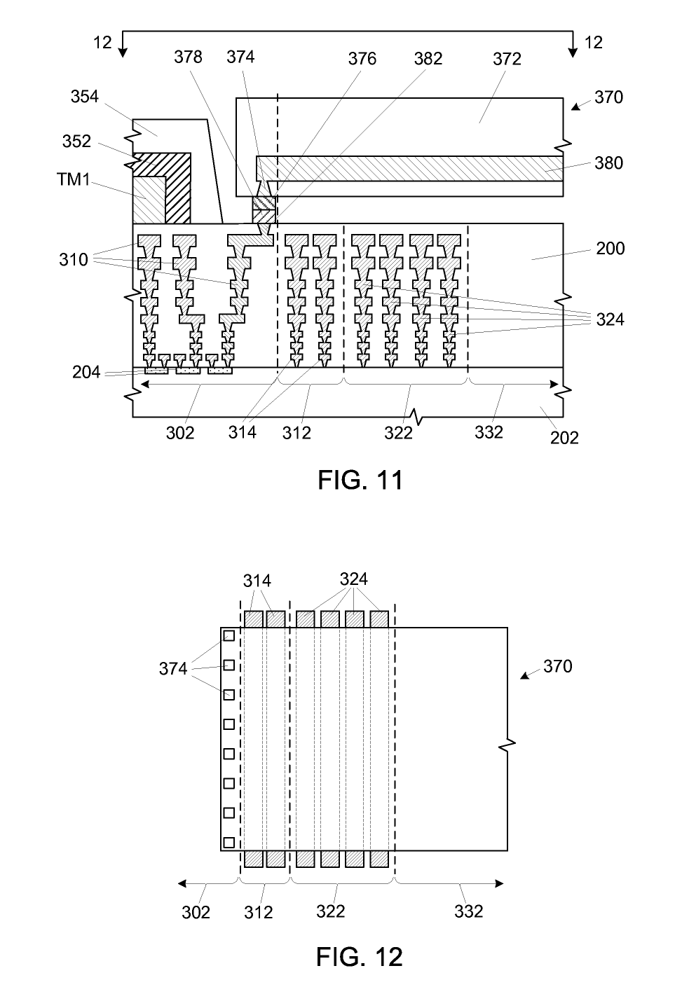

FIG. 11 illustrates still another embodiment of an in-street die-to-die interconnect 380 of the present description, and FIG. 12 illustrates the embodiment illustrated in FIG. 11, along line 12-12, with all elements removed with the exception of the elements numbered in FIG. 12. The in-street die-to-die interconnect 380 of the present embodiment may be formed entirely separately from the interconnection layer 200, as a part of a bridge 370 that extends over the guard ring area 312, the moat area 322, and the dicing street area 332. The bridge 370 may comprise a substrate 372 having the in-street die-to-die interconnects 380 extending therein or thereon. The substrate 372 can be made out of any appropriate substantially rigid material, included but not limited to semiconductor materials (such as silicon), dielectric materials, or combinations thereof. It is understood that the thickness of the bridge 370 may be such that it does not interfere with subsequent packaging.

The in-street die-to-die interconnect 380 may be in electrical connection to a bond pad 376 through a conductive via 374, which may be, in turn, attached to a bond pad 378 formed on the interconnect layer 200. The interconnect layer bond pad 378 may be in electrical communication with at least one active area communication route 310 (such as through a conductive via 382). The bridges 370 may be attached to form the electrical connection between the microelectronic dice 102 of a selected grouping, as can be seen in FIG. 2, prior to singulation.

It is understood that the bridge 370 may include additional circuitry (not shown), both passive and/or active. For example, the bridge 370 contain repeaters associated with the in-street die-to-die interconnect 380, which may be need at high signaling speeds. The additional circuitry (not shown) may be power through connections similar to the conductive via 374 and interconnect layer bond pad 378.

Although the illustrated embodiments in FIG. 1-12 are directed to two core processors with associated cache memory, it is understood that the any type of integrated circuit or microelectronic system may utilize the concepts of the present description. It is understood that with the microelectronic die 102 illustrated, necessary input/output devices may be on a separate microelectronic dice (not shown) that may be connected to the microelectronic dice 102 by high-speed, high density die-to-die interconnects enabled by packaging schemes, such as silicon bridges, bumpless buildup layer/wafer (BBUL-W) technology, silicon interposers, or other multi-chip package (MCP) solutions allowing for the necessary microelectronic die to microelectronic die bandwidth. Furthermore, although the structures forming the interconnects have been described a metal interconnects, it is understood that the interconnects may comprise optical waveguides or fluidic conduits.

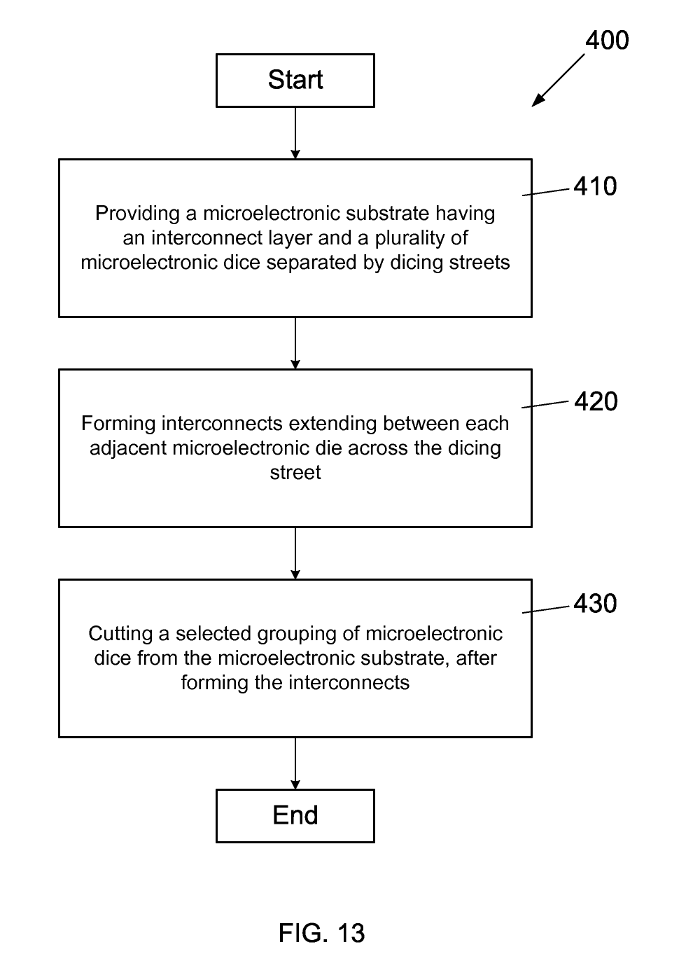

An embodiment of a process of forming a microelectronic device of the present description is illustrated in the flow diagram 400 of FIG. 13. As defined in block 410 of FIG. 13, a microelectronic substrate may be provided having an interconnect layer and a plurality of microelectronic dice separated by dicing streets. Interconnects may be formed to extend between each adjacent microelectronic de across the dicing street, as defined in block 420 of FIG. 13. As defined in block 430 of FIG. 13, a selected grouping of microelectronic dice may be cut from the microelectronic substrate, after forming the interconnects.

The detailed description has described various embodiments of the devices and/or processes through the use of illustrations, block diagrams, flowcharts, and/or examples. Insofar as such illustrations, block diagrams, flowcharts, and/or examples contain one or more functions and/or operations, it will be understood by those skilled in the art that each function and/or operation within each illustration, block diagram, flowchart, and/or example can be implemented, individually and/or collectively, by a wide range of hardware, software, firmware, or virtually any combination thereof.

The described subject matter sometimes illustrates different components contained within, or connected with, different other components. It is understood that such illustrations are merely exemplary, and that many alternate structures can be implemented to achieve the same functionality. In a conceptual sense, any arrangement of components to achieve the same functionality is effectively “associated” such that the desired functionality is achieved. Thus, any two components herein combined to achieve a particular functionality can be seen as “associated with” each other such that the desired functionality is achieved, irrespective of structures or intermediate components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

It will be understood by those skilled in the art that terms used herein, and especially in the appended claims are generally intended as “open” terms. In general, the terms “including” or “includes” should be interpreted as “including but not limited to” or “includes but is not limited to”, respectively. Additionally, the term “having” should be interpreted as “having at least”.

The use of plural and/or singular terms within the detailed description can be translated from the plural to the singular and/or from the singular to the plural as is appropriate to the context and/or the application.

It will be further understood by those skilled in the art that if an indication of the number of elements is used in a claim, the intent for the claim to be so limited will be explicitly recited in the claim, and in the absence of such recitation no such intent is present. Additionally, if a specific number of an introduced claim recitation is explicitly recited, those skilled in the art will recognize that such recitation should typically be interpreted to mean “at least” the recited number.

The use of the terms “an embodiment,” “one embodiment,” “some embodiments,” “another embodiment,” or “other embodiments” in the specification may mean that a particular feature, structure, or characteristic described in connection with one or more embodiments may be included in at least some embodiments, but not necessarily in all embodiments. The various uses of the terms “an embodiment,” “one embodiment,” “another embodiment,” or “other embodiments” in the detailed description are not necessarily all referring to the same embodiments.

While certain exemplary techniques have been described and shown herein using various methods and systems, it should be understood by those skilled in the art that various other modifications may be made, and equivalents may be substituted, without departing from claimed subject matter or spirit thereof. Additionally, many modifications may be made to adapt a particular situation to the teachings of claimed subject matter without departing from the central concept described herein. Therefore, it is intended that claimed subject matter not be limited to the particular examples disclosed, but that such claimed subject matter also may include all implementations falling within the scope of the appended claims, and equivalents thereof.

What is claimed is:

1. A microelectronic device, comprising:
a microelectronic module having an interconnect layer formed thereon;
a plurality of microelectronic dice comprising an integrated circuit formed in and on the microelectronic module, each of the plurality of microelectronic dice having at least one adjacent microelectronic die separated by a dicing street; and
at least one interconnect extending between each adjacent microelectronic die across the dicing street connecting at least one active area communication route of each microelectronic die with an active area communication route of the at least one adjacent microelectronic die.

2. The microelectronic device of claim 1, wherein at least a portion of the at least one interconnect extends through the interconnect layer.

3. The microelectronic device of claim 2, wherein the at least one interconnect comprises at least one conductive trace formed with an uppermost layer of the interconnect layer.

4. The microelectronic device of claim 2, wherein the at least one interconnect comprises at least one conductive trace formed with an uppermost layer of the interconnect layer and at least one bridge structure formed on the interconnect layer.

5. The microelectronic device of claim 4, further including a plurality of guard rings formed within the interconnect layer to surround each microelectronic die, and wherein each bridge structure bridges over the guard ring to electrically connect the at least one active area communication route to the at least one conductive trace.

6. The microelectronic device of claim 2, wherein the at least one interconnect comprises at least one metal bridge embedded within an upper dielectric layer of the interconnect layer.

7. The microelectronic device of claim 2, wherein the at least one interconnect comprises at least one metal bridge embedded within an upper dielectric layer of the interconnect layer and at least one conductive trace formed with an uppermost metal layer of the interconnect layer.

8. The microelectronic device of claim 7, further includes a plurality of guard rings formed within the interconnect layer to surround each microelectronic die, and wherein each embedded metal bridge bridges over the guard ring to electrically connect at least one active area communication route to at least one conductive trace.

9. The microelectronic device of claim 1, wherein the at least one interconnect extends over the interconnect layer within at least one bridge.

10. The microelectronic die module of claim 9, wherein the at least one bridge comprises a substrate having the at least one interconnect formed therein or thereon.

11. A method of fabricating a microelectronic die module, comprising:
providing a microelectronic substrate having an interconnect layer formed thereon and having a plurality of microelectronic dice comprising integrated circuits formed in and on the microelectronic substrate, each of the plurality microelectronic die having at least one adjacent microelectronic die separated by a dicing street;
forming at least one interconnect extending between each adjacent microelectronic die across the dicing street, which connects at least one active area communication route of each microelectronic die with an active area communication route of the at least one adjacent microelectronic die; and
cutting a selected grouping of microelectronic dice from the microelectronic substrate, after forming the at least one interconnect.

12. The method of claim 11, wherein forming the at least one interconnect comprises forming at least one interconnect having a portion thereof extending through the interconnect layer.

13. The method of claim 12, wherein forming at least one interconnect comprises forming at least one conductive trace with an uppermost metal layer of the interconnect layer.

14. The method of claim 12, wherein forming the at least one interconnect comprises forming at least one conductive trace with a uppermost layer of the interconnect layer and forming at least one bridge structure on the interconnect layer.

15. The method of claim 14, further including forming a plurality of guard rings within the interconnect layer to surround each microelectronic die, and wherein forming each bridge structure comprises forming the bridge structure over the guard ring to electrically connect the at least one active area communication route to the at least one conductive trace.

16. The method of claim 12, wherein forming the at least one interconnect comprises embedding at least one metal bridge within an upper dielectric layer of the interconnect layer.

17. The method of claim 12, wherein forming the at least one interconnect comprises embedding at least one metal bridge within an upper dielectric layer of the interconnect layer and forming at least one conductive trace with an uppermost metal layer of the interconnect layer.

18. The method of claim 17, further includes forming a plurality of guard rings within the interconnect layer to surround each microelectronic die, and wherein forming the embedded metal bridge comprises forming the embedded metal bridge over the guard ring to electrically connect at least one active area communication route to the at least one conductive trace.

19. The method of claim 11, wherein forming the at least one interconnect comprises forming the at least one interconnect extending over the interconnect layer within at least one bridge.

20. The method of claim 19, wherein forming the at least one interconnect extending over the interconnect layer within at least one bridge comprises providing a substrate and forming the at least one interconnect therein or thereon.
